(19) United States
(12) Patent Application Publication
(10) Pub. No.: US 2015/0206738 A1
(43) Pub. Date: Jul. 23, 2015

(54) Surface Cleaning Method and Apparatus Using Surface Acoustic Wave Devices

(71) Applicant: SEMATECH, Inc., Albany, NY (US)

(72) Inventor: Abbas Rastegar, Schenectady, NY (US)

(73) Assignee: SEMATECH, Inc., Albany, NY (US)

(21) Appl. No.: 14/159,970

(22) Filed: Jan. 21, 2014

(51) Int. Cl. H01L 21/02; B08B 3/12

(52) U.S. Cl. CPC H01L 21/02052; B08B 3/12

(57) ABSTRACT

An apparatus, system, and method for cleaning surfaces is presented. One embodiment of the system includes an array of surface acoustic wave (SAW) transducers coupled to a substrate. The system may include a positioning mechanism coupled to at least one of a target surface or the array of SAW transducers, and configured to position the array of SAW transducers within an effective cleaning distance of a target surface. The system may also include a cleaning liquid supply arranged to provide cleaning liquid for coupling the array of SAW transducers to the target surface. The system may further include a controller coupled to the array of SAW transducers and configured to activate the array of SAW transducers. At least one of the SAW transducers may be formed to focus cleaning liquid on a focal point and jet cleaning liquid in a direction substantially out of the place of the SAW transducer.

### BACKGROUND OF THE INVENTION

1. Field of the Invention

This invention relates generally to semiconductors and more particularly relates to an apparatus, system, and method for cleaning surfaces involved in semiconductor manufacturing.

2. Description of the Related Art

In semiconductor manufacturing, cleanliness is desired in order to improve the yield of acceptable semiconductor chips made during the manufacturing process. Previously, particles have been removed by exposing them to an acoustic wave in a liquid media is through cavitation. An active acoustic transducer can cause cavitation, and the collapse of cavitation bubbles create surface flows that dislodge particles.

Megasonic cleaners that utilize cavitation by generating acoustic waves with frequencies in the range of 0.5 to 3.0 MHz have been used for removing particles with diameters larger than 50 nanometers from surfaces. Particle removal efficiency increases as the frequency of acoustic waves increases. Particle removal efficiency also increases with acoustic power density. Typically, large acoustic transducers, for example 10 millimeters thick, have been used to create sufficient acoustic power densities. But since typical transducer materials have resonant frequencies inversely proportional to size, the frequency range of large transducers and the particle removal efficiency of megasonic cleaners have been limited. Thus, the ability of megasonic cleaners to safely remove particles smaller than 50 nanometers with high resonant frequencies has also been limited.

In addition, typical acoustic wave transducers lack the ability to create directional flows, for example, flows substantially parallel to the surface being cleaned, and such lack of directionality limits the cleaning effectiveness of such devices.

The referenced shortcomings are not intended to be exhaustive, but rather are among many that tend to impair the effectiveness of previously known techniques concerning particle removal from surfaces in semiconductor manufacturing processes; however, those mentioned here are sufficient to demonstrate that the methodologies appearing in the art have not been satisfactory and that a significant need exists for the techniques described and claimed in this disclosure.

### SUMMARY OF THE INVENTION

From the foregoing discussion, it should be apparent that a need exists for an improved system, apparatus, and method for cleaning particles from surfaces.

A system is presented for safely removing particles from surfaces. In one embodiment the system includes an array of surface acoustic wave (SAW) transducers coupled to a substrate. The system may include a positioning mechanism coupled to at least one of a target surface and the array of SAW transducers or a combination of SAW and acoustic transducers, and configured to position the array of SAW transducers or a combination of SAW and acoustic transducers within an effective range of the target surface. The system may also include a cleaning liquid supply arranged to provide cleaning liquid for coupling the array of SAW transducers to the target surface. The system may further include a controller coupled to the array of SAW transducers and configured to activate the array of SAW transducers.

In certain embodiments, the array of SAW transducers may be further configured to directly excite a particles on the target surface with acoustic waves at one or more frequencies in the range of 1 Megahertz to 10 Gigahertz from the array of SAW transducers.

In certain embodiments, the array of SAW may include a first group of SAW transducers configured to operate at a first frequency and a second group of SAW transducers configured to operate at a second frequency. The first group SAW transducers and the second group of SAW transducers may be intermixed.

In certain embodiments, the controller may further include a first switch, coupled to a first SAW transducer and configured to selectively activate the first acoustic transducer, and a second switch, coupled to a second transducer and configured to selectively activate the second SAW transducer.

In certain embodiments, the individual SAW transducers may have a substantially concentric structure resulting in surface flow toward a focal point and jetting of liquid from the focal point in a direction away from the surface. The substantially concentric structure may include interdigitated arcuate electrodes mounted to the surface.

An apparatus is also presented for removing particles from surfaces. In one described embodiment, the apparatus includes a substrate, an array of SAW transducers coupled to the substrate, and a cleaning liquid supply arranged to provide cleaning liquid for coupling the array of SAW transducers to the target surface. The array of SAW transducers may be configured to directly excite particles on the target surface with acoustic waves at one or more frequencies in the range of 1 megahertz to 10 gigahertz from the array of SAW transducers.

In a further embodiment, the array of SAW transducers in the apparatus may include a first group of SAW transducers configured to operate at a first frequency and a second group of SAW transducers configured to operate at a second frequency. The first group of SAW transducers and the second group of SAW transducers may be intermixed.

A method is also presented for removing particles from a surface. The method in the disclosed embodiments substantially includes the steps necessary to carry out the functions presented above with respect to the operation of the described apparatus and system. In one embodiment, the method includes providing an array of SAW transducers, positioning the array of SAW transducers within an effective distance of a target surface, coupling the array of SAW transducers to the target surface via a cleaning liquid, and directly exciting particles on the target surface with acoustic waves at one or more frequencies in the range of 1 megahertz to 10 gigahertz from the array of SAW transducers. The individual SAW transducers may have a substantially concentric structure resulting in surface flow toward a focal point and jetting of liquid from the focal point in a direction away from the surface.

Certain embodiments may include focusing the acoustic waves from the array of SAW transducers on a point or on a plurality of points. Other embodiments may include focusing the acoustic waves from the array of SAW transducers on a line or on a plurality of lines. Further embodiments may include coupling the SAW transducers to a two-dimensional plane.

The term “coupled” is defined as connected, although not necessarily directly, and not necessarily mechanically.

The terms “a” and “an” are defined as one or more unless this disclosure explicitly requires otherwise.

The term “substantially” and its variations are defined as being largely but not necessarily wholly what is specified as understood by one of ordinary skill in the art, and in one non-limiting embodiment “substantially” refers to ranges within 10%, preferably within 5%, more preferably within 1%, and most preferably within 0.5% of what is specified.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The invention may be better understood by reference to one or more of these drawings in combination with the detailed description of specific embodiments presented herein.

FIG. 1 is a schematic block diagram illustrating one embodiment of a system for removing particles from a surface.

FIGS. 2A and 2B are schematic views illustrating one embodiment of the disclosure for cleaning surfaces.

FIG. 3 is a schematic cross-section diagram illustrating another embodiment of the disclosure for cleaning surfaces.

FIG. 4 is a three dimensional schematic cross-section diagram illustrating another embodiment of the disclosure for cleaning surfaces.

FIG. 5 is a schematic bottom view illustrating another embodiment of the disclosure for cleaning surfaces.

FIG. 6 is a schematic bottom view illustrating another embodiment of the disclosure for cleaning surfaces.

FIG. 7 is a schematic block diagram illustrating one embodiment of a system for selectively activating individual SAW transducers for cleaning surfaces.

FIGS. 8A, 8B and 8C are schematic cross-section diagrams illustrating embodiments of the disclosure for cleaning surfaces.

FIGS. 9A, 9B, 9C and 9D are graphs illustrating embodiments of a low frequency pulse and a high frequency pulse combinations.

FIG. 10 is a schematic flow chart diagram illustrating one embodiment of a method for cleaning particles from a surface.

FIGS. 11A and 11B are schematics of a surface acoustic wave (SAW) usable as an acoustic transducer in the present disclosure.

FIG. 12 is another schematics of a SAW usable as an acoustic transducer in the present disclosure.

FIGS. 13A, 13B, 13C and 13D are schematics of other SAW's usable as acoustic transducers in the present disclosure.

FIG. 14 is a schematic of yet another SAW usable as an acoustic transducer the present disclosure.

FIGS. 15A and 15B are schematics of yet another SAW usable as an acoustic transducer in the present disclosure

FIGS. 16A and 16B are schematics of yet other SAW usable as an acoustic transducer in the present disclosure

FIGS. 17 and 18 are schematic bottom views illustrating other embodiments for cleaning surfaces.

FIGS. 19 and 20 are schematic bottom views illustrating other embodiments for cleaning surfaces.

FIG. 21 is a schematic bottom view illustrating another embodiment for cleaning surfaces.

FIG. 22 is a schematic bottom view illustrating another embodiment for cleaning surfaces.

### DETAILED DESCRIPTION

Various features and advantageous details are explained more fully with reference to the nonlimiting embodiments that are illustrated in the accompanying drawings and detailed in the following description. Descriptions of well-known starting materials, processing techniques, components, and equipment are omitted so as not to unnecessarily obscure the invention in detail. It should be understood, however, that the detailed description and the specific examples, while indicating embodiments of the invention, are given by way of illustration only, and not by way of limitation. Various substitutions, modifications, additions, and/or rearrangements within the spirit and/or scope of the underlying inventive concept will become apparent to those skilled in the art from this disclosure.

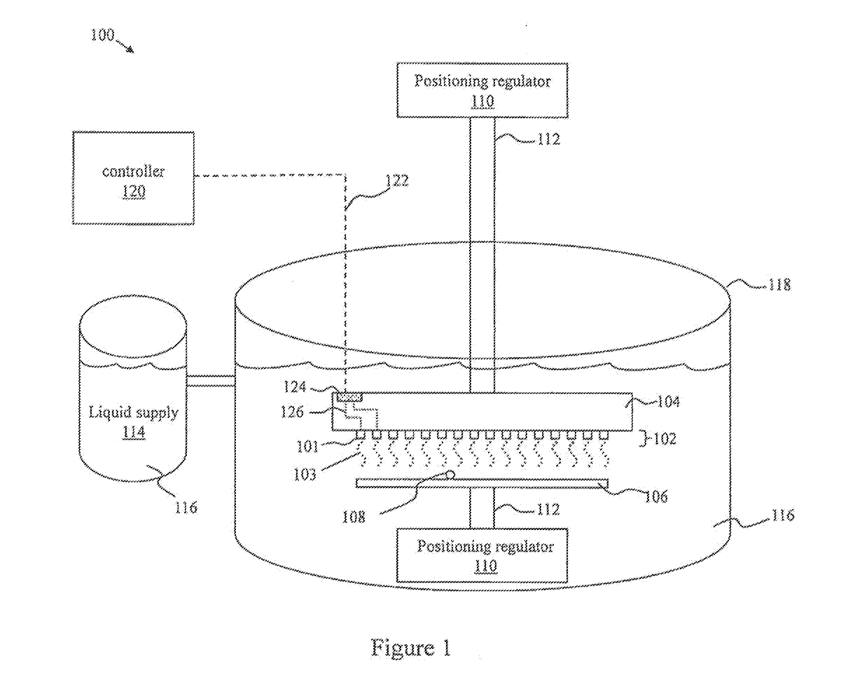

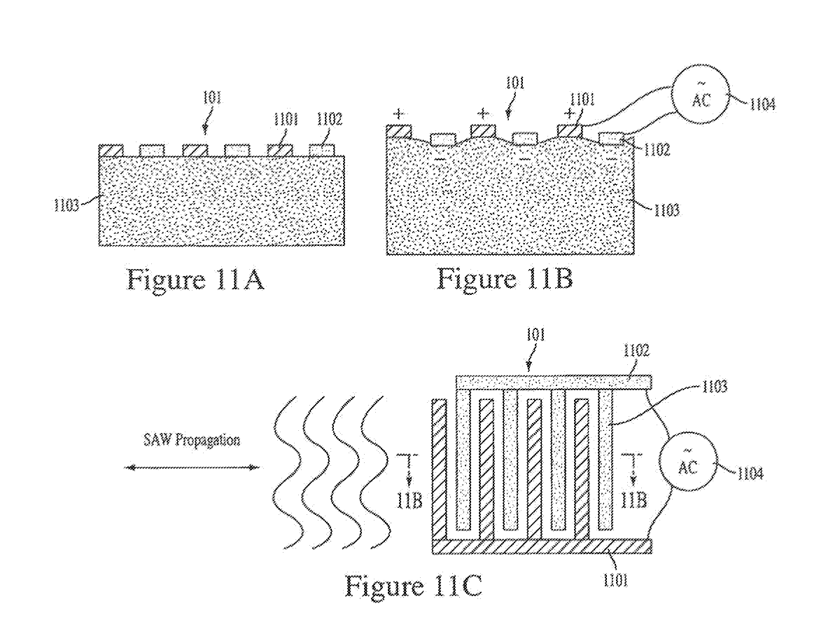

FIG. 1 describes one embodiment of a system 100 for cleaning surfaces. The system 100 may include an array 102 of acoustic transducers 101 which includes individual acoustic transducers 101. Acoustic transducers 101 may be surface acoustic wave (SAW) transducers as described in more detail with reference to FIGS. 11-22. The size of SAW transducers 101, and the material that comprises the SAW transducers 101 may cause the array 102 of SAW transducers 101 to emit acoustic waves 103 with frequencies in the range of 1 megahertz to 10 gigahertz. The SAW transducers 101 may generate acoustic waves 103 at or around the resonant frequency of a particle 108, directly exciting the particle 108, and causing the particle 108 to dislodge from the target surface 106. In alternative embodiments, the disclosed system 100 may cause direct excitation alone to remove particles, or it may cause direct excitation in conjunction with other mechanisms, such as cavitation and mega/gigasonic streaming for particle removal.

As illustrated in FIG. 1, the system 100 may include an array 102 of SAW transducers 101 coupled to a substrate 104. Though the diagram in FIG. 1 is not to scale, the array 102 of SAW transducers 101 may be positioned close to a target surface 106. The system 100 may include a supply 114 of one or more cleaning liquids 116 and a tank 118. The tank 118 may hold the cleaning liquid 116 that couples the array 102 of SAW transducers 101 to the target surface 106 and the particle 108. A positioning mechanism 112 may be coupled to at least one of the array 102 of SAW transducers 101 and the target surface 106. A positioning regulator 110 may control the positioning mechanism 112 and set the position of the array 102 of SAW transducers 101 relative to the target surface 106. A controller 120 may activate and deactivate the array 102 of SAW transducers 101 by sending a signal or signals, or applying a voltage. In one embodiment, the controller 120 may be coupled to a signal bus 122. An interface 124 on the substrate 104 may couple the signal bus 122 to the internal routing 126 which is coupled to the SAW transducers 101.

In semiconductor manufacturing, cleanliness is desired in order to improve the yield of acceptable semiconductor chips made during the manufacturing process. In certain embodiments, the target surface 106 may be a semiconductor wafer. In alternative embodiments, the target surface 106 may be a liquid crystal display, a photolithography mask, or another surface, including, but not limited to, surfaces involved in a semiconductor manufacturing process.

An array 102 of SAW transducers 101 may include individual SAW transducers 101. In one embodiment, the array 102 of SAW transducers 101 may be coupled to a substrate 104. The substrate 104 may be comprised of substrate materials such as silicon, quartz, lithium niobate, silicon carbide, or other materials that are suitable for coupling SAW transducers 101 to the substrate 104. In a further embodiment, the substrate 104 may comprise piezoelectric transducer materials configured with electrodes to form one or more SAW devices.

The array 102 of SAW transducers 101 may be coupled to the target surface 106 through a cleaning liquid 116. In some embodiments, the cleaning liquid 116 may be water. The water may be deionized, distilled, or purified by other means. In some embodiments, the cleaning liquid 116 may be a chemical solution.

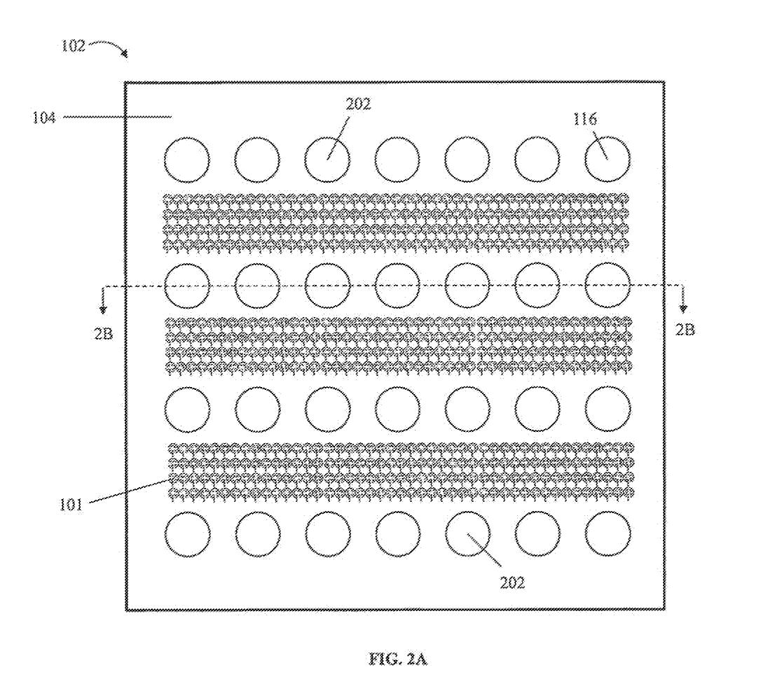

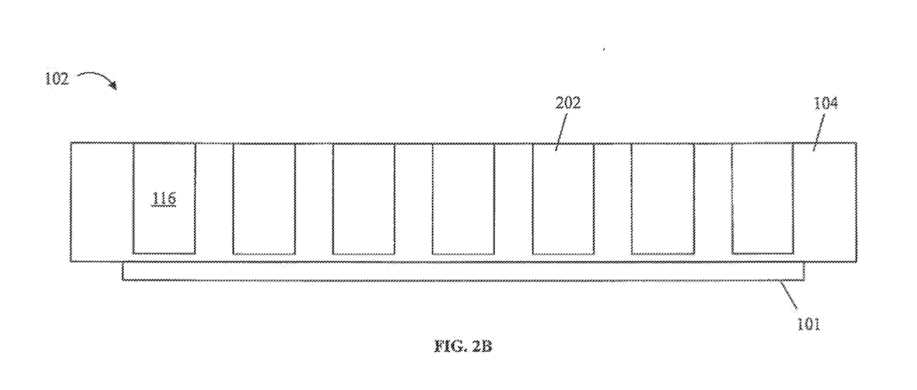

In one embodiment, cleaning liquid supply 114 may dispense the cleaning liquid 116 into the tank 118. The array 102 of SAW transducers 101 and the target surface 106 may be coupled to each other through the cleaning liquid 116 when they are immersed in the cleaning liquid 116 in the tank 118. In an alternate embodiment (not shown), the cleaning liquid 116 may be dispensed between the array 102 of acoustic transducers 101 and the target surface 106 by a spray configuration (not shown). As illustrated in FIGS. 2A and 2B, the cleaning liquid 116 may be dispensed from spray holes 202 contained in the substrate 104, with substrate 104 also supporting array 102 of SAW transducers 101.

In one embodiment, acoustic waves 103 generated by the array 102 of SAW transducers 101 may be absorbed by the cleaning liquid 116 as the acoustic waves 103 travel across a distance in the cleaning liquid 116. Because higher frequency acoustic waves may be absorbed by the cleaning liquid 116 faster than lower frequency acoustic waves, the application range may vary depending upon the frequency of the acoustic waves 103 being emitted from the array 102 of SAW transducers 101. In certain embodiments of the system 100, the positioning mechanism 112 may adjust the position the array 102 of acoustic transducers 101 to within an effective distance, for example, 1 millimeter of the target surface 106. In different embodiments, the positioning mechanism 112 may position the array 102 of SAW transducers 101 at different distances from the target surface 106, depending in part on the frequency or frequencies of the acoustic waves 103 being emitted and the rate at which the acoustic waves 103 dissipate in the cleaning liquid 116. For example, positioning mechanism may position array 102 of transducers 101 from 0.2 to 5.0 millimeters from target surface 106, depending on the composition of cleaning liquid and the structure and operation frequency of transducers 101 and their distribution within array 102.

In some embodiments, a positioning mechanism 112 may be coupled either directly to at least one of the substrate 104 and the target surface 106, or indirectly to at least one of the substrate 104 and the target surface 106 through one or more coupling members (not shown). In a particular embodiment, the positioning regulator 110 is coupled to the positioning mechanism 112, and is configured to control the position of the array 102 of SAW transducers 101 and/or the target surface 106 by moving the positioning mechanism 112. In alternative embodiments, a positioning mechanism 112 may be coupled to one of the substrate 104 and the target surface 106. In some alternative embodiments, a positioning mechanism 112 may be connected to the substrate 104 but not to the target surface 106. The target surface 106 may be in a static position during the positioning of the array 102 of SAW transducers 101. In other embodiments, a positioning mechanism 112 may be coupled to the target surface 106 but not to the substrate 104. The array 102 of SAW transducers 101 may be in a static position during the positioning of the target surface 106.

As illustrated, the positioning regulator 110 may include a first portion coupled to the brush 104 and a second portion coupled to the surface to be cleaned 106. In such an embodiment, the first portion and the second portion may operate substantially independently and position the brush and the wafer in three dimensional space.

A positioning regulator 110 may include a machine or machines executable instructions. For example, a positioning regulator 110 may include a hardware circuit comprising custom VLSI circuits or gate arrays, off-the-shelf semiconductors such as logic chips, transistors, or other discrete components. A positioning regulator 110 may also include programmable hardware devices such as processors, special purpose microprocessors, field programmable gate arrays, programmable array logic, programmable logic devices or the like.

The positioning regulator 110 may also include software modules, which may include software-defined units or instructions, that when executed by a processing machine or device, transform data stored on a data storage device from a first state to a second state. An identified module of executable code may, for instance, comprise one or more physical or logical blocks of computer instructions which may be organized as an object, procedure, or function. Nevertheless, the executables of an identified module need not be physically located together, but may comprise disparate instructions stored in different locations which, when joined logically together, comprise the module, and when executed by the processor, achieve the stated data transformation.

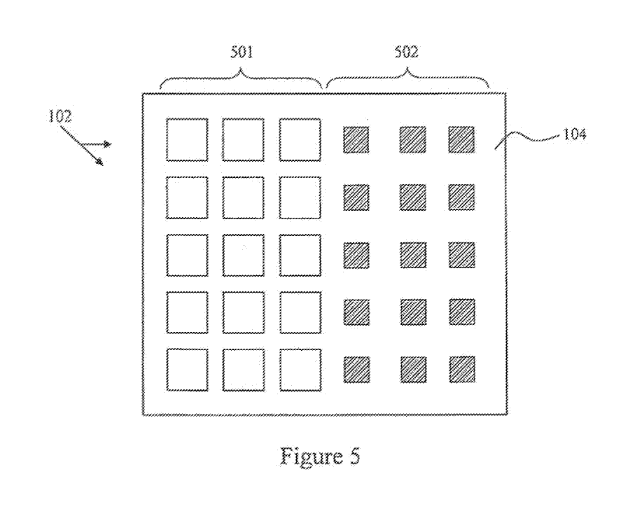

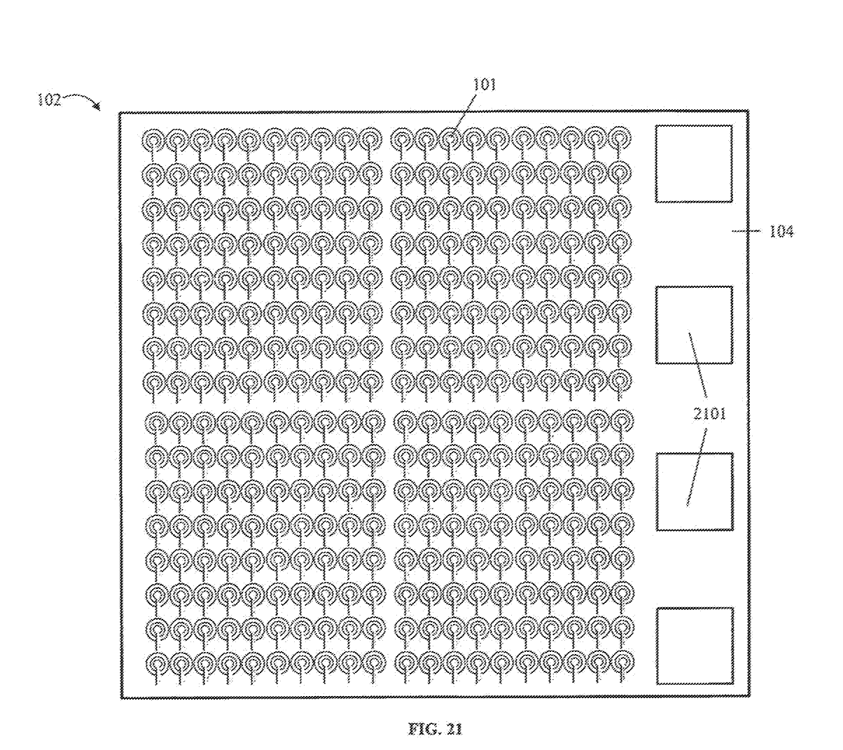

In one embodiment, the system 100 includes a controller 120 that activates some or all of the SAW transducers 101 in an array 102. The controller may send an activation signal or activation signals through a signal bus 122. An interface 124 on the substrate 104 may connect the signal bus 122 to the internal routing 126, which couples to the acoustic transducers 101 in the array 102. In some embodiments, the controller 120, signal bus 122, interface 124, and internal routing 126 may be configured to send a single activation signal to the entire array 102 of SAW transducers 101. In other embodiments, the controller 120, signal bus 122, interface 124, and internal routing 126 may be configured to send separate activation signals to different individual acoustic transducers 101 and groups of individual SAW transducers 101 within an array 102 of SAW transducers 101 (see FIGS. 5-7 and 18-20). In further embodiments, the controller 120, signal bus 122, interface 124, and internal routing 126, may be configured to send separate activation signals to each individual SAW transducers 101 within an array 102 of SAW transducers 101. An activation signal may be the activation power that is required to activate one or more SAW transducers, or an enabling signal for control circuitry (not shown) that may be built on the substrate 104 and that directs activating power to one or more of the acoustic transducers 101 in the array 102 (see, FIG. 21). Controller 120 will provide the appropriate excitation signals to the SAW transducers 101 to cause formation of surface acoustic waves.

Controller 120 may include a machine or machines executable instructions. For example, controller 120 may be implemented as a hardware circuit comprising custom VLSI circuits or gate arrays, off-the-shelf semiconductors such as logic chips, transistors, or other discrete components. A controller 120 may also be implemented in programmable hardware devices such as processors, special purpose microprocessors, field programmable gate arrays, programmable array logic, programmable logic devices or the like.

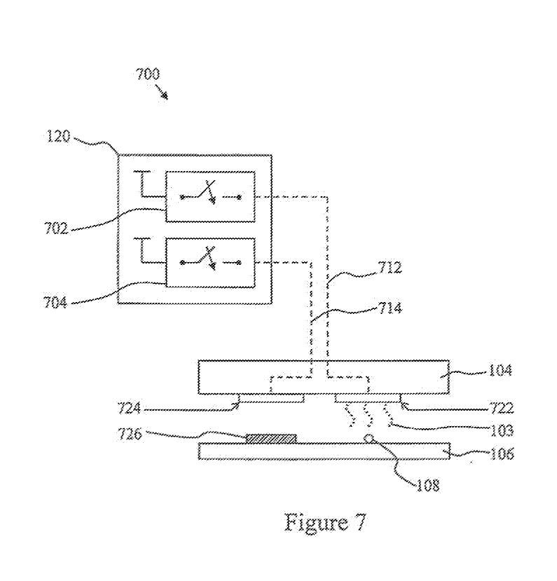

Controller 120 may also include software modules, which may include software-defined units or instructions, that when executed by a processing machine or device, transform data stored on a data storage device from a first state to a second state. An identified module of executable code may, for instance, comprise one or more physical or logical blocks of computer instructions which may be organized as an object, procedure, or function. Nevertheless, the executables of an identified module need not be physically located together, but may comprise disparate instructions stored in different locations which, when joined logically together, comprise the module, and when executed by the processor, achieve the stated data transformation. Further embodiments of the controller are described below with reference to FIG. 7.

FIGS. 2A and 2B illustrate a bottom view and a cross section, respectively, of one embodiment where an array 102 of SAW transducers 101 are configured in a two-dimensional plane on a substrate 104. In some embodiments, the substrate 104 may include spray holes 202 configured to dispense cleaning liquid 116 into the gap between the array 102 of SAW transducers 101 and the target surface 106. In some embodiments, the one or more spray holes 202 may be intermixed with the array 102 of SAW transducers 101. In other embodiments, one or more spray holes 202 may be placed near the edge of the substrate 104 or in any place suitable for dispensing cleaning liquid 116 into an area between the array 102 of SAW transducers 101 and the target cleaning surface 106. Although the transducers 101 have been illustrated in FIGS. 2A and 2B with a square layout, one of ordinary skill in the art will recognize other suitable shapes for the transducer shape may be implemented.

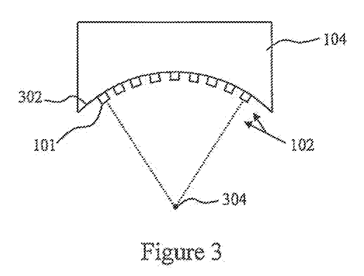

FIG. 3 is a cross-section view of one embodiment where the substrate 104 has a concave surface 302. The array 102 of SAW transducers 101 may be coupled to the concave surface 302, and acoustic waves 103 may be focused on a focus point 304. In other embodiments, the substrate 104 may contain multiple concave surfaces 302, and acoustic waves 103 may be focused on a plurality of focus points 304.

In some embodiments of the system 100, the positioning regulator 110 may control the positioning mechanism 112 to position the substrate 104, having one or more concave surfaces 302, relative to the target surface 106 in a manner which may align one or more focus points 304 with a desired location or locations on the target surface 106. In some embodiments, the positioning regulator 110 may control the position of the substrate 104 having one or more concave surfaces 302 and the position of the target surface 106 in such a manner that one or more focus points 304 are in a static position relative to the target surface 106 while the SAW transducers 101 are active. In other embodiments, the positioning regulator 110 may control the position of the substrate 104 having one or more concave surface 302 and the position of the target surface 106 in such a manner that the focus point 304 moves relative to the target surface 106 while the SAW transducers 101 are active.

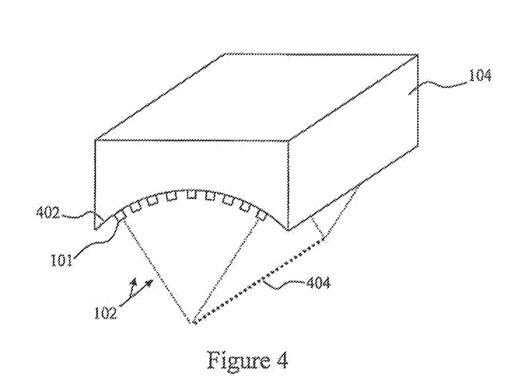

FIG. 4 is a cross-section view of one embodiment where the substrate 104 has a semi-cylindrical surface 402. The array 102 of SAW transducers 101 may be coupled to the semi-cylindrical surface 402, and acoustic waves 103 may be focused on a focus line 404. In other embodiments, the substrate 104 may contain multiple semi-cylindrical surfaces 402, and acoustic waves 103 may be focused on a plurality of focus lines 404.

In some embodiments of the system 100, the positioning regulator 110 may control the positioning mechanism 112 to position a substrate 104, having one or more semi-cylindrical surfaces 402, relative to the target surface 106 in a manner which may align one or more focus lines 404 with a desired location or locations on the target surface 106. In some embodiments, the positioning regulator 110 may control the position of the substrate 104 having one or more semi-cylindrical surfaces 402 and/or the position of the target surface 106 in such a manner that one or more focus lines 404 are in a static position relative to the target surface 106 while the SAW transducers 101 are active. In other embodiments, the positioning regulator 110 may control the position of the substrate 104 having one or more semi-cylindrical surfaces 402 and the position of the target surface 106 in such a manner that one or more focus lines 404 move relative to the target surface 106 while the SAW transducers 101 are active.

FIG. 5 illustrates a bottom view of one embodiment of the array 102 of SAW transducers 101 coupled to a substrate 104. The array 102 may comprise a first group 501 of SAW transducers and a second group 502 of SAW transducers. The first group 501 may be configured to operate at a first frequency, and the second group 502 may be configured to operate at a second frequency. In some embodiments, the first group 501 may have a first size, and the second group may have a second size. In some embodiments, the first group 501 comprise a first transducer material, and the second group 502 may comprise a second transducer material.

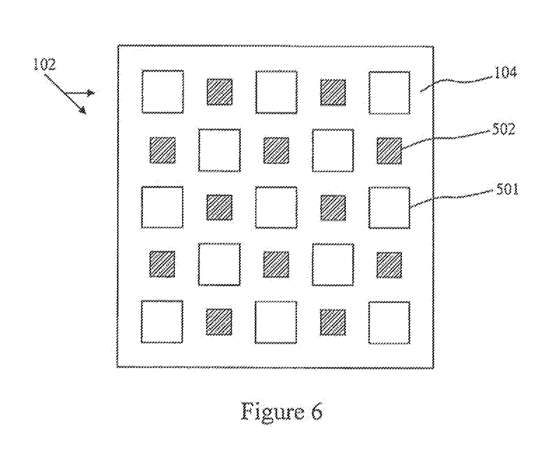

FIG. 6 illustrates a bottom view of one embodiment where an array 102 of SAW transducers 101 are coupled to a substrate 104. The array 102 may comprise a first group 501 of SAW transducers 101 and a second group 502 of SAW transducers 101. The first group 501 of SAW transducers 101 and the second group 502 of SAW transducers 101 may be intermixed.

Referring to FIG. 7, some target surfaces 106, including semiconductor wafers, may be sensitive to acoustic waves 103. In some situations, it may be desirable to limit the amount of acoustic energy applied to all or a portion of the target surface 106. In some other situations, it may be desirable to emit acoustic energy in the vicinity of some portions of the target surface 106 to clean those portions of the target surface, and to not emit acoustic energy in the vicinity of other portions of the target surface to avoid damage to sensitive patterns 726 on a target surface 106. Thus it may be desirable to activate one or more SAW transducers 101 in the array 102 while selecting to not activate one or more of the other SAW transducers 101 in the array 102.

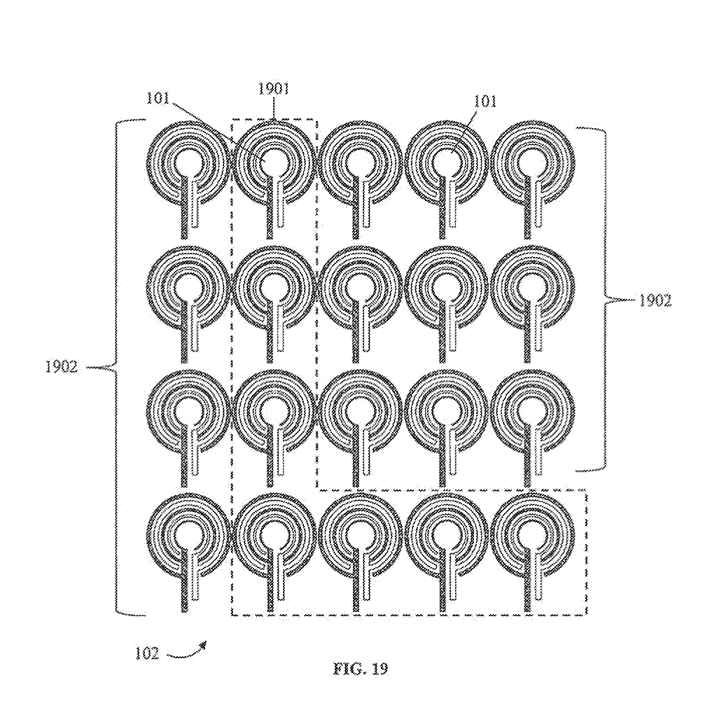

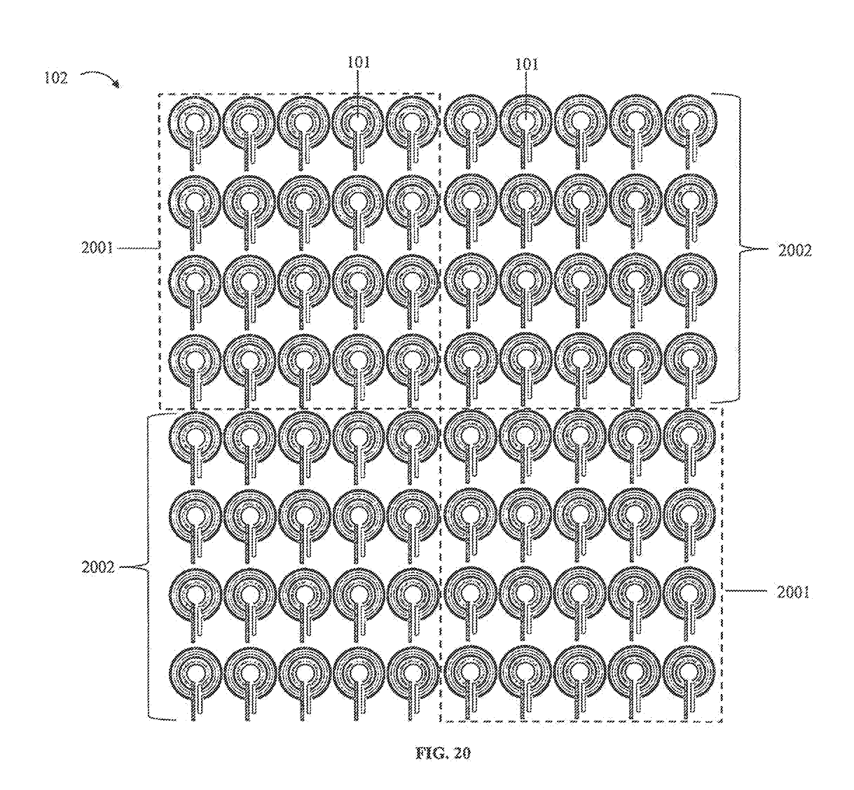

FIG. 7 is one embodiment of a system 700 that includes a controller 120 configured to selectively activate a first SAW transducer 722 and selectively activate a second SAW transducer 724. The controller 120 may comprise a first switch 702 and a second switch 704. The first switch 702 may be coupled to the first SAW transducer 722 via a first signal line 712. The second switch 704 may be coupled to the second SAW transducer 724 via a second signal line 714. In one embodiment, the controller 120 may select to turn on the first switch 702 to activate the first SAW transducer 722, and select to turn off the second switch 704 to deactivate the second SAW transducer 724 which may be aligned with a sensitive pattern 726 on the target surface 106. Other examples of selective activation and deactivation of SAW transducers 101 are shown in FIGS. 19 and 20

In other embodiments, the controller 120 may select to deactivate the first SAW transducer 722 and select to deactivate the first acoustic transducer 722, or the controller may select to activate both the first SAW transducer 722 and the second SAW transducer 724, or the controller may select to deactivate both the first SAW transducer 722 and the second SAW transducer 724.

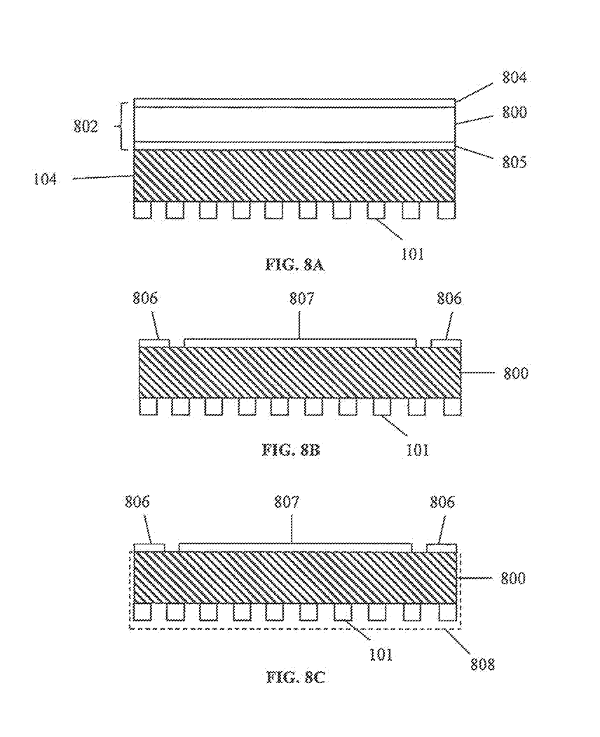

FIGS. 8A, 8B and 8C illustrate various embodiments of a brush 100 for cleaning a surface 106. In one embodiment, the brush 100 may include a plurality of SAW transducers 101. The SAW transducers 101 may operate in the 1 MHz to 10 GHz range of frequencies. In such an embodiment, the SAW transducers 101 may be coupled to a substrate 104.

The Piezoelectric material 800 may include lithium niobate and tantalate, zinc oxide, aluminum nitride, lead-zirconate-titanate and gallium arsenide, crystalline quartz, and the like. Some of these piezoelectrics are cut from a larger crystal, an example being the familiar quartz crystal shear-mode crystal employed in the quartz crystal microbalance (QCM). Films of these piezoelectrics are also important. They are produced by a variety of means, including: sputtering (from the pure element in a reactive chemical gas or from a compound source), pulsed laser deposition (ablation from a compound target upon which intense laser pulses are incident), chemical vapor deposition (CVD), spun-on polymeric piezoelectrics, and the solÈgel technique (spin-on deposition of chemical precursors in an organic binder that is later vaporized). Magnetic, electrostatic and thermal acoustic excitation means are also available.

In a further embodiment, an additional low frequency transducer 802 configured to operate in the MHz frequency range may be coupled to the substrate 104. For example, the transducer 802 may include a piezoelectric material 800 coupled to a electrodes 804 and 805. In such an embodiment, the brush may emit both waves in the GHz range and the MHz range simultaneously, or substantially simultaneously. As illustrated in FIG. 8A, the high frequency SAW transducers 101 mounted on substrate 104 may be build or mounted upon the low frequency transducer 802, with electrodes 804, 805 of low frequency transducer 802 located on the top and bottom of piezoelectric material 800 as show. Alternatively, as shown in FIGS. 8B and 8C, low frequency transducer 802 may be formed by applying electrodes 806, 807 to a top surface of piezoelectric material 800, with SAW transducers 101 formed on the bottom surface of piezoelectric material 800. In FIG. 8C, a protective layer 808 may be applied over SAW transducers 101. Protective layer 808. Protective layer 808 is preferably low in attenuation of the acoustic energy produced by SAW transducers 101 while at the same time providing protection for transducers 101 from the deleterious effects of cleaning liquid 116. For example, protective layer 808 may be a layer of silicon dioxide deposited by sputtering and having a thickness of between 10 and 50 nanometers. Alternatively, protective layer 808 may be a polymer, such as polyimide, deposited by spin coating and cured using ultraviolet and/or thermal processing. Other types of materials for protective layer 808 and other application techniques may also be acceptable without departing from the scope of the disclosure.

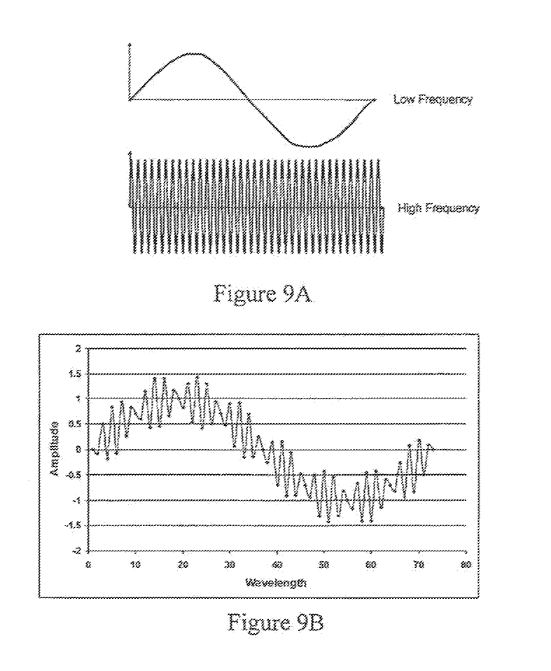

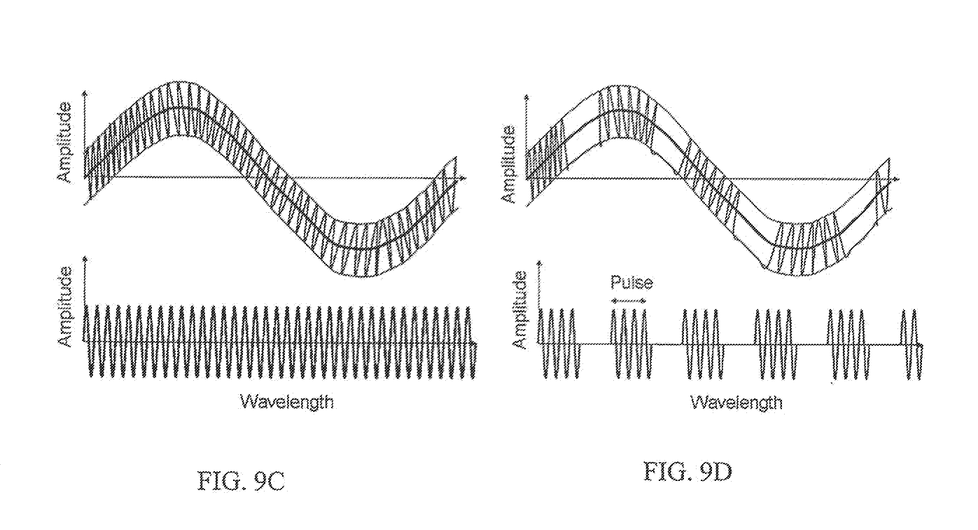

FIG. 9A illustrates a graph of a low frequency signal (i.e., a MHz frequency pulse) that may be generated by the low frequency piezoelectric transducer 802 as well as a high frequency signal (i.e., a GHz frequency pulse) that may be generated by the SAW transducer 101. As illustrated in FIG. 9B, when both the low frequency transducer 802 and the SAW transducers 101 are operated simultaneously, the resultant acoustic signal may include a high frequency wave superimposed on, or concatenated with, a low frequency wave as shown.

In the mode described in FIGS. 9C-9D, multiple mechanisms are involved in particle removal, GHZ waves may do direct excitation and provide surface flow, and MHZ waves can create cavitations and finally megasonic streaming also is present in this configuration. All these high and low frequency components can work in pulse mode. Both duration of a pulse number of pulses may be controlled.

The schematic flow chart diagrams that follow are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

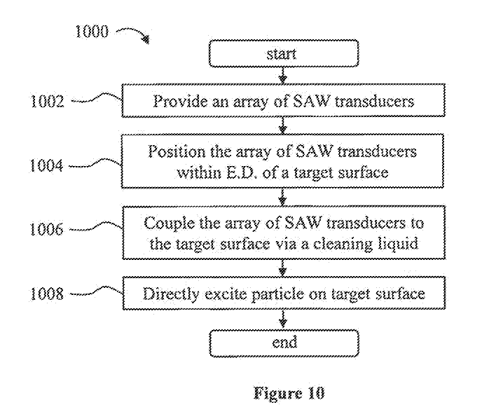

FIG. 10 illustrates one embodiment of a method 1000 for cleaning surfaces. In one embodiment, the method 1000 may include providing 1002 an array 102 of SAW transducers 101 and positioning 1004 the array 102 of acoustic transducers 101 within an effective distance of a target surface 106. Additionally, the method 1000 may include coupling 1006 the array 102 of SAW transducers 101 to the target surface 106 via a cleaning liquid 116, and directly exciting 1008 a particle 108 on the target surface 106. Some embodiments may directly excite 1008 a particle 108 with acoustic waves 103 at one or more frequencies in the range of 1 Megahertz to 10 Gigahertz from the array 102 of SAW transducers 101.

In the example embodiment, a positioning mechanism 112, coupled to the substrate 104 and the array 102 of acoustic transducers 101, may position the array 102 of acoustic transducers 101 at a predetermined distance from the target surface 106. The target surface 106 may be a semiconductor wafer. In the example embodiment, a cleaning liquid 116, comprised of deionized water and dispensed into a tank 118, may couple the array 102 of SAW transducers 101 to the semiconductor wafer 106. A controller 120, may selectively activate SAW transducers 101. The array 102 of SAW transducers 101 may directly excite a particle 108 on the semiconductor wafer 106.

Some embodiments of method 1000 may further include coupling the array 102 of SAW transducers 101 to a two dimensional plane. Other embodiments may include focusing the acoustic waves 103 from the array 102 of SAW transducers 101 on a point 304. Some embodiments may further include focusing the acoustic waves 103 from the array 102 of SAW transducers 101 on a line 404.

In certain embodiments of method 1000, providing 1002 an array 102 of SAW transducers 101 may further include providing a first group 501 of SAW transducers 101 configured to operate at a first frequency and providing a second group 502 of SAW transducers 101 configured to operate at a second frequency. In some embodiments, the SAW transducers 101 in the first group 501 and the SAW transducers 101 in the second group 502 may have different sizes. In another embodiment, the SAW transducers 101 in the first group 501 and the SAW transducers in the second group 502 may be comprised of different materials. In some embodiments, the acoustic transducers 101 in the first group 501 and the acoustic transducers 101 in the second group 502 may have different sizes and may be comprised of different materials.

Some embodiments of method 1000 may further include selectively activating the first SAW transducer 722 and selectively activating the second SAW transducer 724. In some embodiments, the first SAW transducer 722 may be aligned with a portion of the target surface 106 that is desired to be cleaned while the second SAW transducer 724 may be aligned with a sensitive pattern 726. The first SAW transducer 722 may be selected to be active and may clean a portion of the target surface 106. The second SAW transducer 724 may be selected to not be active and may avoid emitting acoustic waves 103 in the vicinity of the sensitive pattern 726 on the target surface 106.

In some embodiments, the first SAW transducer 722 may be selected to not be active, and the second SAW transducer 724 may be selected to be active. In other embodiments, the first SAW transducer 722 and the second SAW transducer 724 may both be selected to be active at the same time. In other embodiments, the first SAW transducer 722 and the second SAW transducer 724 may both be selected to not be active at the same time.

Referring to FIGS. 11A, 11B and 11C, an acoustic transducer 101 is disclosed in the form of a surface acoustic wave (SAW) transducer including first and second interdigitated electrodes 1101 and 1102 disposed on a substrate 1103 made of piezoelectric material, which may include, for example, lithium niobate and tantalate, zinc oxide, aluminium nitride, lead-zirconate-titanate and gallium arsenide, crystalline quartz, and the like. FIG. 11A is a schematic of a SAW transducer without any applied excitation voltage. FIG. 11B is a cross-section of FIG. 11C and is a schematic of a SAW transducer with an applied excitation voltage from alternating current source 1104. Alternating current source 1104 may be part of controller 120 (FIG. 1). The surface deformation of piezoelectric substrate 1103 in FIG. 11B is not to scale. FIG. 11C is an example of a layout of interdigitated electrodes 1101 and 1102 on the surface of substrate 1103, and illustrates the direction of SAW propagation along the surface of substrate 1103 in a direction that is substantially longitudinal relative to the surface of substrate 1103.

The operating frequency of the SAW transducers 101 of the disclosure is determined by the width and spacing of the interdigitated electrodes 1101 and 1102. The surface acoustic wave propagates across the surface as a Raleigh wave having a wavelength λ which is determined by the width and spacing of electrodes 1101 and 1102. The width and spacing of electrodes 1101 and 1102 are preferably equal to each other, and equal to λ/4. This, in turn, determines the operating frequency (resonant frequency) of the SAW, f=c/λ, where c is the speed of the SAW in the substrate. For example, when the substrate 1103 is lithium niobate, c≈3965 m/s. Other substrate materials may have different SAW propagation speeds, which will result in different geometries for electrodes 1101, 1102 for a desired operating frequency. Alternatively, electrodes 1101, 1102 having substantially identical geometries, will have different operating frequencies depending on the composition of substrate 1103. In this way, SAW transducers 101 may be made to operate at different frequencies.

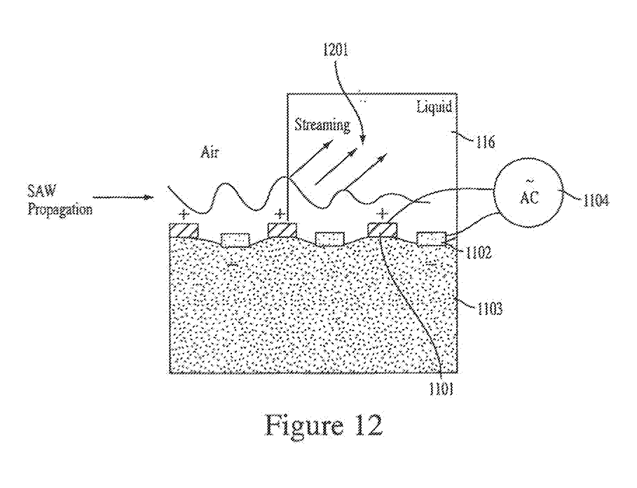

Referring to FIG. 12, when SAW transducer 101 it contacted by a liquid, for example cleaning liquid 116, liquid streaming 1201 occurs in a direction along the surface of substrate 1103 with a component of the streaming 1201 being substantially parallel to the surface of substrate 1103 and a component of streaming 1201 being substantially normal to the surface of substrate 1103.

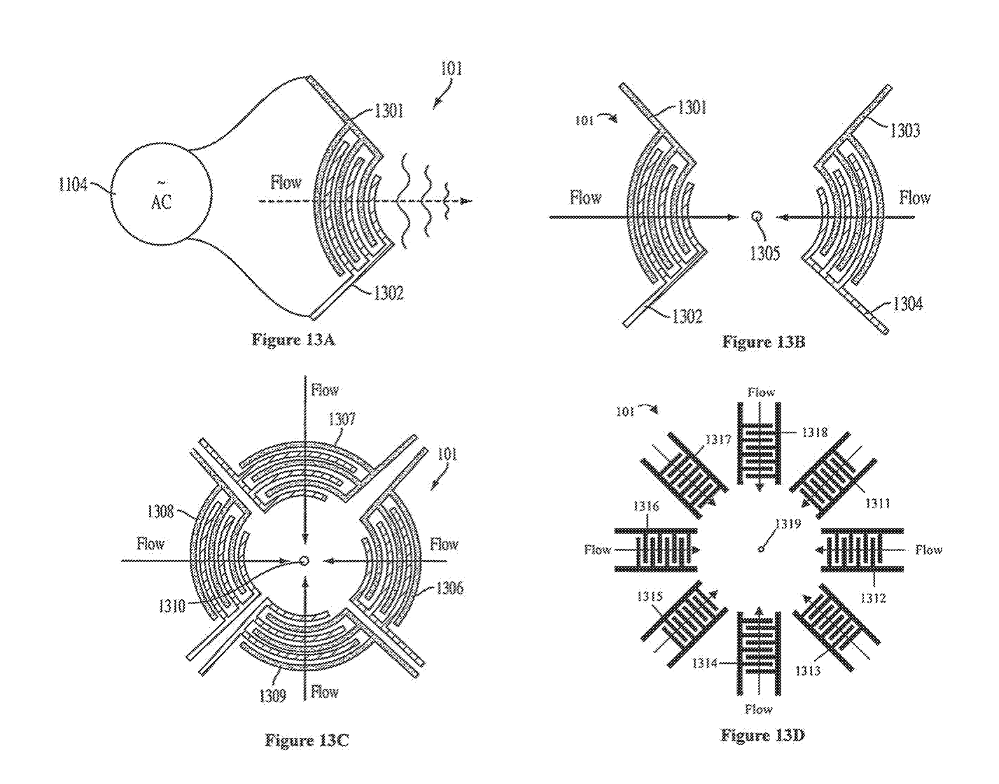

Referring to FIG. 13A, presented is a schematic of a SAW transducer 101 having electrodes 1301 and 1302 configured as interdigitated substantially concentric arcs together forming a focused SAW. FIGS. 13B and 13C are schematics of SAW transducers 101 employing a plurality of focused SAW devices. FIG. 13B is a schematic of an embodiment of a SAW transducer 101 having a first set of electrodes 1301, 1302 configured of a first set of interdigitated substantially concentric arcs, and a second set of electrodes 1303, 1304 configured as a second set of interdigitated substantially concentric arcs, the first and second sets forming two focused SAWs with opposing focused liquid flows having a substantially common focal point 1305. FIG. 13C is a schematic of yet another SAW transducer 101 including first, second third and fourth sets, 1306, 1307, 1308 and 1309 of electrodes, each forming a focused SAW device and each configured as interdigitated substantially concentric arcs that produce focused liquid flows with a substantially common focal point 1310. Other configurations of a plurality of sets of focused SAWs are also contemplated. For example, interdigitated electrodes having geometric shapes other than arcuate are also acceptable. For example, interdigitated electrodes with triangular, rectangular (including square) pentagonal or hexagonal shapes, may also be acceptable without departing from the scope of the disclosure. FIG. 13D provides yet another example of a focused SAW device 101 comprised of eight individual SAW structures 1311-1318, each of which force liquid flow toward focal point 1319. While the eight SAW structures in FIG. 13D are shown arranged in four opposing pairs of interdigitated electrodes, it will be understood that one or more opposing pairs of interdigitated electrodes may be used without departing from the scope of the disclosure. For example SAW structures 1316, 1319 may be used alone to form a single opposing pair of interdigitated electrodes. Saw structures 1314, 1318 may be used in combination structures 1316, 1318 to form two opposing pairs of interdigitated electrodes, and so forth. Use of pairs of opposing focused SAW transducers, as shown in FIGS. 13B, 13C and 13D, will result in jetting of liquid in a direction substantially out of the plane of the electrodes, and originating substantially in the vicinity of focal points 1305, 1310, 1319. For example, the liquid jetting may be substantially perpendicular to the plane of the electrodes.

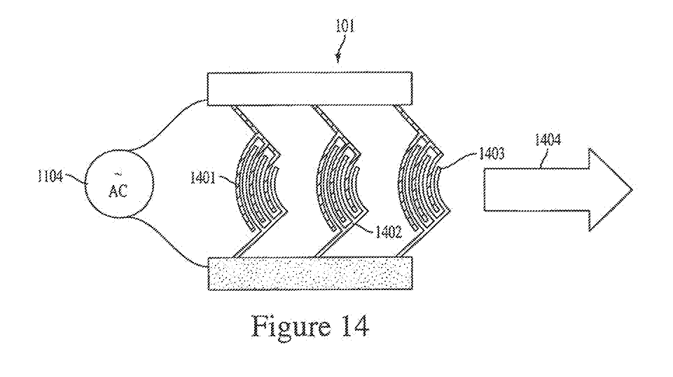

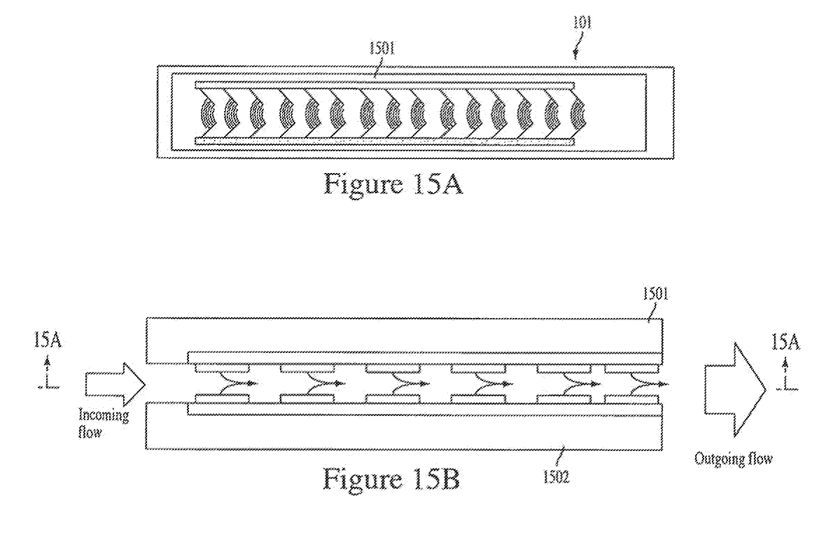

Referring now to FIG. 14, presented is a schematic of SAW transducer 101 according to an embodiment of the present disclosure, including a plurality of focused SAW devices 1401, 1402 and 1403, each configured as interdigitated substantially concentric arcs that produce constructive focused liquid flows resulting in common high speed liquid flow 1404.

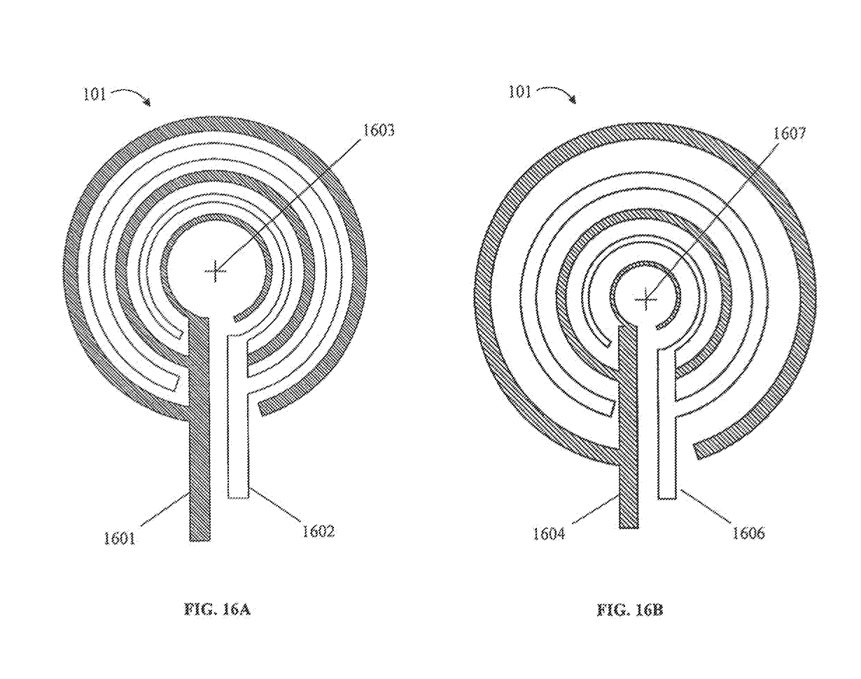

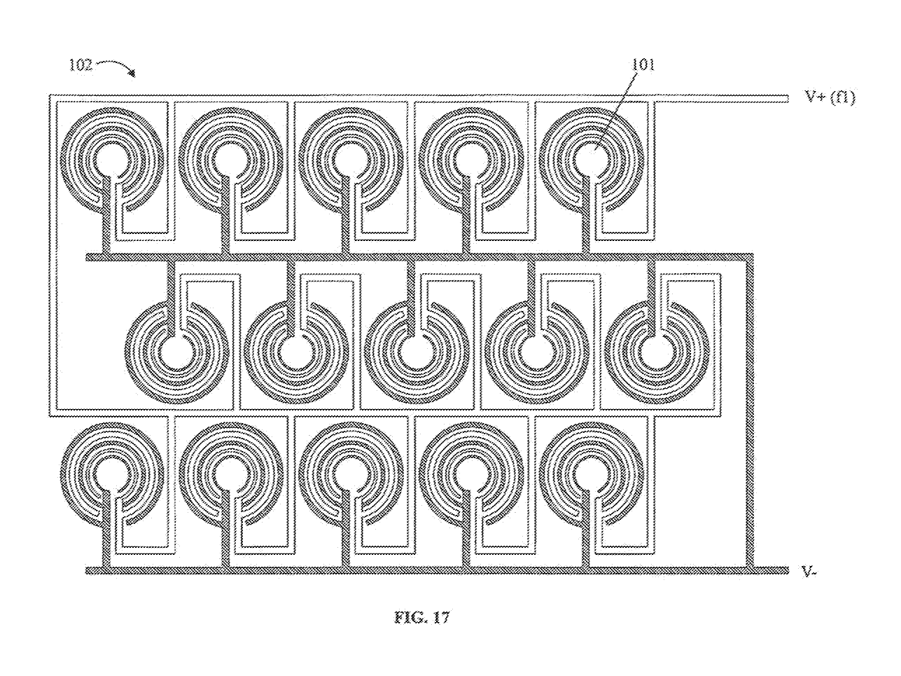

FIGS. 15A and 15B are schematic views of a SAW transducer 101 in the form of a high speed fluid nozzle including first and second sets, 1501, 1502, of focused SAW devices together forming a high speed liquid flow nozzle, producing high speed liquid flow 1503.

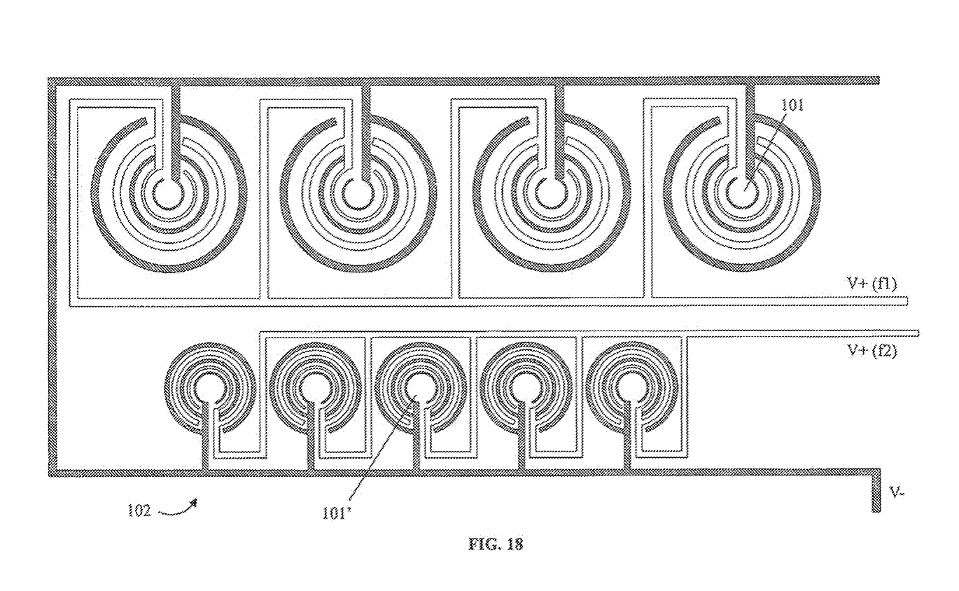

FIGS. 16A and 16B present schematic views of another embodiment of SAW transducer 101 having different operating frequencies. Each SAW transducer 101 in FIGS. 16A and 16B is configured as interdigitated sets of arcuate electrodes having a common center. Once again, geometric shapes other arcuate may also be acceptable. In FIG. 16A, arcuate electrodes 1601, 1602 each surround a common center 1603, and in FIG. 16B, arcuate electrodes 1604, 1606 each surround a common center 1607. As shown, electrodes 1601, 1602 form a SAW having a smaller diameter than the SAW formed by electrodes 1604, 1606. Thus, assuming a common piezoelectric substrate material, the SAW of FIG. 16A would have a higher operating frequency than the operating frequency of the SAW of FIG. 16B.

Referring back to FIG. 12, it should be noted that SAW transducer 101 may act as an acoustic transducer, either to produce surface waves, or as an acoustic detector to detect surface waves. Since piezoelectric materials have permanent dipole moments, mechanical deformation of a SAW transducer will create electric charge which will be transferred to the SAW electrodes. For example, in FIG. 12 surface deformation will create voltage in SAW electrodes 1101, 1102. Thus, structures similar to that of FIG. 16 may be used as an acoustic sensor, or hydrophone, for measuring an intensity of incident acoustic waves.

FIG. 17 illustrates an array 102 of SAW transducers 101 of a configuration like that shown in FIG. 16B with all transducers 101 operating at a single frequency f1. FIG. 18 illustrates an array 102 of SAW transducers 101, 101′ with a first group 102A having a configuration like that shown in FIG. 16A with an operating frequency f2, and a second group 102B having a configuration like that shown in FIG. 16B with an operating frequency f1 that is lower than frequency f2. It should be noted that any number of SAW transducers having different operating frequencies may be combined on a single substrate without departing from the scope of the disclosure.

FIGS. 19 and 20 illustrate arrays 102 of selectively activated SAW transducers 101. As mentioned above with reference to FIG. 7, system 700 of controller 120 may be used to selectively activate and deactivate SAW transducers 101 in any desired pattern. For example, in FIG. 19, SAW transducers 101 in group 1901 may be activated separately from or together with SAW transducers 101 in group 1902. In a similar fashion, with reference to FIG. 20, SAW transducers 101 in group 2001 may be activated together with or separately from SAW transducers 101 in group 2002.

FIG. 21 is an example of array 102 of SAW transducers 101 formed on a common substrate 104 along with supporting electronic circuits 2101. Circuits 2101 may include, for example controller 120 and/or circuitry associated with positioning regulator 110 (FIG. 1).

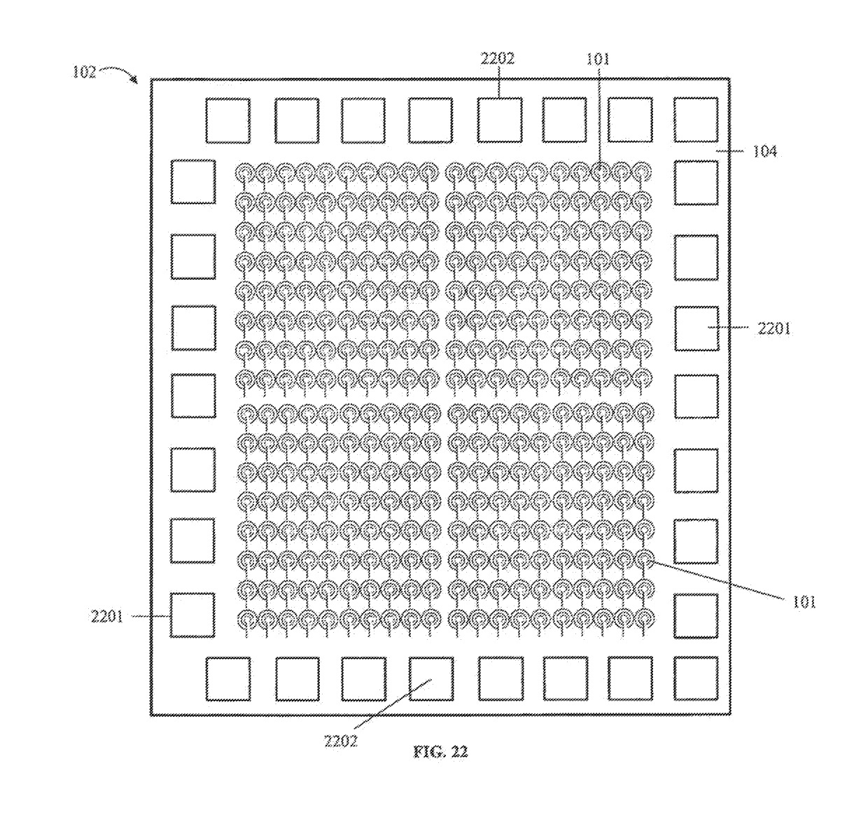

FIG. 22 is a system 100 including an array 102 of SAW transducers 101 in combination with ultraviolet (UV) light sources 2201, 2202 to provide an additional cleaning process that uses ultraviolet radiation to disassociate chemical bonds that exist between contaminant particles and the target surface. UV light sources 2201, 2202 may have the same or different UV frequencies. Such UV light cleaning processes are shown in more detail in U.S. Pat. No. 7,921,859, the disclosure of which is expressly incorporated herein by reference. It should also be noted that at least some of elements 2201, 2201 may be replaced by SAW devices acting as acoustic sensors to detect an acoustic energy being reflected from a target surface. In addition or in the alternative, one or more SAW transducers 101 within array 102 may be used as SAW devices acting as acoustic sensors.

All of the methods disclosed and claimed herein can be made and executed without undue experimentation in light of the present disclosure. While the apparatus and methods of this invention have been described in terms of preferred embodiments, it will be apparent to those of skill in the art that variations may be applied to the methods and in the steps or in the sequence of steps of the method described herein without departing from the concept, spirit and scope of the invention. In addition, modifications may be made to the disclosed apparatus and components may be eliminated or substituted for the components described herein where the same or similar results would be achieved. All such similar substitutes and modifications apparent to those skilled in the art are deemed to be within the spirit, scope, and concept of the invention as defined by the appended claims.

What is claimed is:

1. A method comprising:
providing an array of surface acoustic wave (SAW) transducers;
positioning the array of SAW transducers within an effective cleaning distance of a target surface;
coupling the array of SAW transducers to the target surface via a cleaning liquid; and
directly exciting a particles on the target surface with acoustic waves at one or more frequencies in the range of 1 Megahertz to 10 Gigahertz from the array of SAW transducers.

2. The method of claim 1, further comprising focusing the acoustic waves from the array of SAW transducers on a point.

3. The method of claim 1, further comprising focusing the acoustic waves from the array of SAW transducers on a line.

4. The method of claim 1, further comprising coupling the array of SAW transducers to a two dimensional plane.

5. The method of claim 1, the step of providing an array of SAW transducers further comprising providing a first group of SAW transducers configured to operate at a first frequency and providing a second group of SAW transducers configured to operate at a second frequency.

6. The method of claim 5, the first group of SAW transducers and the second group of SAW transducers being intermixed.

7. The method of claim 1, further comprising selectively activating a first SAW transducer and selectively activating a second SAW transducer.

8. The method of claim 4, at least one of the SAW transducers comprising a concentric structure that focuses cleaning liquid on a focal point and jets cleaning liquid from the focal point in a direction substantially out of to the plane.

9. The method of claim 8, the cleaning liquid jetting in a direction substantially perpendicular to the plane.

10. The method of claim 8, further comprising, operating at least one of SAW transduces as an acoustic sensor.

11. A system comprising:
an array of surface acoustic wave (SAW) transducers;
a positioning mechanism coupled to at least one of a target surface and the array of SAW transducers and configured to position the array of SAW transducers within an effective cleaning distance of the target surface;
a cleaning liquid supply arranged to provide cleaning liquid for coupling the array of SAW transducers to the target surface; and
a controller coupled to the array of SAW transducers and configured to activate the array of SAW transducers.

12. The system of claim 11, the array of SAW transducers being further configured to directly excite a particle on the target surface with acoustic waves at one or more frequencies in the range of 1 Megahertz to 10 Gigahertz from the array of SAW transducers.

13. The system of claim 11, at least one of the SAW transducers comprising a set of electrodes in the form of interdigitated substantially concentric structures to focus the acoustic waves from the SAW transducers on a point.

14. The system of claim 13, the substantially concentric structures comprising arcs.

15. The system of claim 11, the array of SAW transducers being coupled to a two-dimensional plane on a substrate.

16. The system of claim 11, the array of SAW transducers comprising a first group of SAW transducers configured to operate at a first frequency and a second group of SAW transducers configured to operate at a second frequency.

17. The system of claim 16, the first group of SAW transducers and the second group of SAW transducers being intermixed.

18. A system of claim 11, the controller further comprising:
a first switch coupled to a first SAW transducer, and configured to selectively activate the first SAW transducer; and
a second switch coupled to a second SAW transducer, and configured to selectively activate the second SAW transducer.

19. An apparatus comprising:
a substrate;
an array of surface acoustic wave (SAW) transducers coupled to the substrate; and
a cleaning liquid supply arranged to provide a cleaning liquid to couple the array of SAW transducers to a target surface.

20. The apparatus of claim 19, the array of SAW transducers further configured to directly excite a particle on the target surface with acoustic waves at one or more frequencies in the range of 1 Megahertz to 10 Gigahertz from the array of SAW transducers.

21. The apparatus of claim 20, the array of SAW transducers comprising a first group of SAW transducers configured to operate at a first frequency and a second group of SAW transducers configured to operate at a second frequency.

22. The apparatus of claim 21, the first group of SAW transducers and the second group of SAW transducers being intermixed.

23. The apparatus of claim 19, further comprising a first SAW transducer configured for selective activation and a second SAW transducer configured for selective activation.

24. The apparatus of claim 19, at least one of the SAW transducers comprising a set of electrodes in the form of interdigitated substantially concentric structures to focus the acoustic waves from the SAW transducers on a point.

25. The apparatus of claim 24, the substantially concentric structures comprising arcs.

26. The apparatus of claim 19, at least one of the SAW transducers operating as an acoustic sensor.
